(19) United States
(12) Patent Application Publication
(10) Pub. No.: US 2024/0215420 A1
(43) Pub. Date: Jun. 27, 2024

(54) ELECTRONIC APPARATUS AND METHOD FOR MANUFACTURING THE SAME

(71) Applicant: Samsung Display Co., LTD., Yongin-si (KR)

(72) Inventors: JUNGHOON SHIN, Yongin-si (KR); JAESANG LEE, Yongin-si (KR); SUNG-WOON IM, Yongin-si (KR)

(21) Appl. No.: 18/244,474

(22) Filed: Sep. 11, 2023

(30) Foreign Application Priority Data
Dec. 27, 2022 (KR) 10-2022-0186070

(51) Int. Cl. H10K 59/80; H01L 23/373; H01L 23/552

(52) U.S. Cl. CPC H10K 59/8794; H01L 23/3733; H01L 23/552; H01L 25/167

(57) ABSTRACT

A method for manufacturing an electronic apparatus includes coating a resin, in which heat dissipation materials and metal particles are dispersed, on a rear surface of a display panel to form a preliminary functional layer, disposing a mask on the preliminary functional layer, inverting the display panel such that the preliminary functional layer is positioned below the display panel, and curing the preliminary functional layer to form a functional layer.

This application claims priority to Korean Patent Application No. 10-2022-0186070, filed on Dec. 27, 2022, and all the benefits accruing therefrom under 35 U.S.C. § 119, the content of which in its entirety is herein incorporated by reference.

### BACKGROUND

### 1. Field

The disclosure herein relates to an electronic apparatus having heat dissipation properties and a method for manufacturing the electronic apparatus.

### 2. Description of the Related Art

Multimedia electronic apparatuses such as televisions, mobile phones, tablets, navigation system units, and game consoles may include a display device for displaying images and electronic components for performing various functions. Since the electronic apparatuses have become high-performance and thin, the electronic components embedded therein have become large-capacity and high-integration. Accordingly, the electronic components generate a lot of heat inside the electronic apparatuses. The heat generated in the electronic apparatuses shorten the lifespan of a product and/or may cause the failure or malfunction of the electronic components and the display device.

### SUMMARY

The disclosure provides an electronic apparatus with reduced thickness and improved heat dissipation performance, and a method for manufacturing the same.

An embodiment provides an electronic apparatus including a display panel configured to display an image, and a functional layer disposed on a rear surface of the display panel, wherein the functional layer includes a base portion including a first surface facing the rear surface and a second surface opposite to the first surface, and heat dissipation materials and metal particles dispersed inside the base portion, wherein the metal particles are distributed more densely in a region closer to the second surface than in a region closer to the first surface.

In an embodiment, the functional layer may be provided as a single layer.

In an embodiment, the first surface of the base portion may contact the rear surface of the display panel.

In an embodiment, the display panel may include a base substrate defining the rear surface and/or light emitting elements disposed on the base substrate, wherein the first surface of the base portion may contact the base substrate.

In an embodiment, the base portion may include a styrene-butadiene rubber material.

In an embodiment, the heat dissipation materials may include a carbon-based heat dissipation material.

In an embodiment, the electronic apparatus may include a plurality of protruded portions protruding from the second surface.

In an embodiment, the electronic apparatus may further include a protective layer disposed in a lower portion of the functional layer, wherein the protruded portions are disposed such that a gap may be formed between the second surface and the protective layer.

In an embodiment, a thermal diffusion coefficient of the functional layer may be about 43 mm²/s.

In an embodiment, a thickness of the functional layer may be about 100 μm to about 350 μm.

In an embodiment, a method for manufacturing an electronic apparatus includes forming a preliminary functional layer by coating a resin, in which heat dissipation materials and metal particles are dispersed, onto a rear surface of a display panel, disposing a mask on the preliminary functional layer, inverting the display panel such that the preliminary functional layer is positioned below the display panel, and forming a functional layer by curing the preliminary functional layer.

In an embodiment, the method for manufacturing an electronic apparatus may further include, after the inverting of the display panel, discharging the resin through a plurality of holes formed in the mask by the pressure of the display panel, and removing the discharged resin.

In an embodiment, the forming the functional layer may further include removing the mask.

In an embodiment, the functional layer may include a plurality of protruded portions respectively corresponding to the plurality of holes of the mask.

In an embodiment, the method for manufacturing an electronic apparatus may further include, after the forming of the functional layer, disposing a protective layer below the plurality of protruded portions.

In an embodiment, the method for manufacturing an electronic apparatus may further include, after the inverting of the display panel, pressurizing the preliminary functional layer.

In an embodiment, the pressurizing of the preliminary functional layer and the curing of the preliminary functional layer may be simultaneously performed.

In an embodiment, the forming the functional layer may further include curing of the preliminary functional layer by thermal curing.

In an embodiment, the method for manufacturing an electronic apparatus may further include, before the inverting of the display panel, pre-curing the preliminary functional layer.

In an embodiment, the pre-curing of the preliminary functional layer may be performed by thermal curing.

### BRIEF DESCRIPTION OF THE DRAWINGS

The above and other features of embodiments of the disclosure will become apparent by describing in detail embodiments thereof with reference to the accompanying drawings.

FIG. 1 is a perspective view of an electronic apparatus according to an embodiment;

FIG. 2 is an exploded perspective view of an electronic apparatus according to an embodiment;

FIG. 3 is a schematic block diagram of an electronic apparatus according to an embodiment;

FIG. 4 is a schematic plan view of a display panel according to an embodiment;

FIG. 5A is a cross-sectional view of a portion of an electronic apparatus according to an embodiment;

FIG. 5B is a cross-sectional view of a display panel according to an embodiment;

FIG. 6 is an enlarged view of a region AA illustrated in FIG. 5A according to an embodiment;

FIG. 7 is a cross-sectional enlarged view of a functional layer according to an embodiment;

FIG. 8A is a cross-sectional view of some steps of a method for manufacturing an electronic apparatus according to an embodiment;

FIG. 8B is a cross-sectional view of some steps of a method for manufacturing an electronic apparatus according to an embodiment;

FIG. 8C is a cross-sectional view of some steps of a method for manufacturing an electronic apparatus according to an embodiment;

FIG. 8D is a cross-sectional view of some steps of a method for manufacturing an electronic apparatus according to an embodiment;

FIG. 8E is a cross-sectional view of some steps of a method for manufacturing an electronic apparatus according to an embodiment;

FIG. 8F is a cross-sectional view of some steps of a method for manufacturing an electronic apparatus according to an embodiment;

FIG. 9A is a cross-sectional view of some steps of a method for manufacturing an electronic apparatus according and an embodiment; and

FIG. 9B is a cross-sectional view of some steps of a method for manufacturing an electronic apparatus according and an embodiment.

### DETAILED DESCRIPTION

The invention may be modified in many alternate forms, and thus specific embodiments will be exemplified in the drawings and described in detail. It should be understood, however, that it is not intended to limit the invention to the particular forms disclosed, but rather, is intended to cover all modifications, equivalents, and alternatives falling within the spirit and scope of the disclosure.

In the disclosure, when an element (or a region, a layer, a portion, etc.) is referred to as being “on,” “connected to,” or “coupled to” another element, it means that the element may be directly disposed on/connected to/coupled to the other element, or that a third element may be disposed therebetween.

Like reference numerals refer to like elements. Also, in the drawings, the thickness, the ratio, and the dimensions of elements are exaggerated for an effective description of technical contents.

The term “and/or” includes any and all combinations of one or more of which associated elements may define.

It will be understood that, although the terms “first,” “second,” etc. may be used herein to describe various elements, these elements should not be limited by these terms. These terms may only be used to distinguish one element from another. For example, a first element may be referred to as a second element, and a second element may also be referred to as a first element in a similar manner without departing the scope of rights of the present invention. The terms of a singular form may include plural forms unless the context clearly indicates otherwise.

In addition, terms such as “below,” “lower,” “above,” “upper,” and the like are used to describe the relationship of components shown in the drawings. The terms are used as a relative concept and are described with reference to the direction indicated in the drawings.

Unless otherwise defined, all terms (including technical and scientific terms) used herein have the same meaning as commonly understood by one of ordinary skill in the art to which the present invention pertains. It is also to be understood that terms defined in commonly used dictionaries should be interpreted as having meanings consistent with the meanings in the context of the related art, and are expressly defined herein unless they are interpreted in an ideal or overly formal sense.

It should be understood that the term “comprise,” or “have” is intended to specify the presence of stated features, integers, steps, operations, elements, components, and/or combinations thereof in the disclosure, but do not preclude the presence and/or addition of one or more other features, integers, steps, operations, elements, components, or combinations thereof.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments will be described with reference to the accompanying drawings.

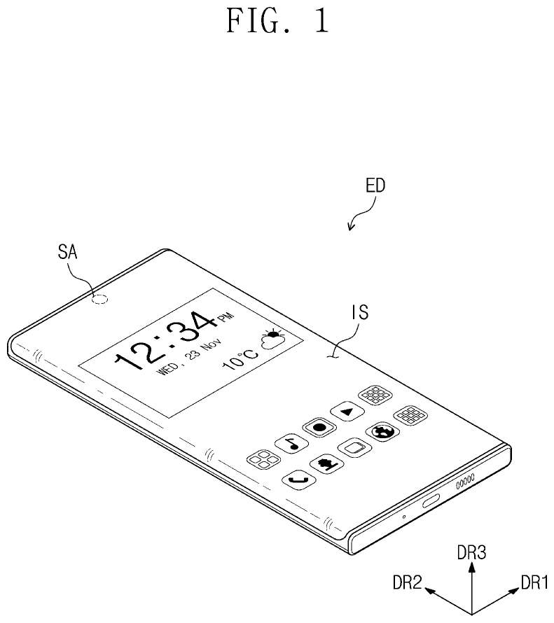

FIG. 1 is a perspective view of an electronic apparatus ED according to an embodiment.

In an embodiment and referring to FIG. 1, the electronic apparatus ED may be a device activated according to an electrical signal and for displaying images. For example, the electronic apparatus ED may be a large-sized apparatus such as a television and/or an external billboard, and may also be a small-and-medium-sized apparatus such as a monitor, a mobile phone, a tablet, a navigation system unit, and/or a game console. However, embodiments of the electronic apparatus ED are only exemplary, and are not limited to any one thereof without departing from the invention. In the embodiment, the electronic apparatus ED is exemplarily illustrated as a mobile phone.

In an embodiment, the electronic apparatus ED may have a rectangular shape which has short sides extended in a first direction DR1 on a plane and long sides extended in a second direction DR2 crossing the first direction DR1. However, the inventive concept is not limited thereto, and the electronic apparatus ED may have various shapes such as a circular shape and a polygonal shape on a plane.

In the embodiment, a third direction DR3 may be defined as a direction perpendicular to a plane defined by first direction DR1 and the second direction DR2. The front surface (or upper surface) and the rear surface (or lower surface) of members constituting the electronic apparatus ED may oppose each other in the third direction DR3, and the normal direction of each of the front surface and the rear surface may be substantially parallel to the third direction DR3. A separation distance between the front surface and the rear surface, which is defined along the third direction DR3, may correspond to the thickness of a member.

In the disclosure, “on a plane” may be defined as a state viewed in the third direction DR3. In the disclosure, “on a cross-section” may be defined as a state viewed in the first direction DR1 or the second direction DR2. Meanwhile, directions indicated by the first to third directions DR1, DR2, and DR3 are a relative concept, and may be converted to different directions.

In an embodiment, the electronic apparatus ED may be rigid or flexible. Being “flexible” refers to having properties of being able to be bent, which may include from a structure of being completely folded to a structure of being able to be bent to a degree of about a few nanometers. For example, a flexible electronic apparatus ED may include a curved apparatus or a foldable apparatus.

In an embodiment, the electronic apparatus ED may display an image through a display surface IS. The display surface IS may correspond to a front surface of the electronic apparatus ED. The display surface IS of the electronic apparatus ED may include a plane on which the first direction DR1 and the second direction DR2 are defined, and may display an image in the third direction DR3 crossing the plane. The display surface IS may further include curved surfaces bent from at least two sides of the plane, respectively. However, the shape of the display surface IS is not limited thereto. For example, in an embodiment, the display surface IS may include only the plane, or may further include four curved surfaces bent from two or more, for example four sides of the plane, respectively.

In an embodiment, a partial region of the display surface IS may be defined as a sensing region SA. FIG. 1 exemplarily illustrates one sensing region SA, but the number of the sensing region SA is not limited thereto. The sensing region SA may be a region having a higher transmittance of an optical signal than other regions in the display surface IS. The sensing region SA may display an image and transmit an optical signal at the same time.

The electronic apparatus ED according to an embodiment may sense an external input applied from the outside. The external input may include various forms of inputs. For example, the external input may include force, pressure, temperature, light, and/or the like. The external input may include not only an input which comes into contract with the electronic apparatus ED (e.g., a contact by a user's hand or a pen), but also an input applied in close proximity to the electronic apparatus ED (e.g., hovering).

In an embodiment, the electronic apparatus ED senses a user's input through the display surface IS defined on the front surface, and may respond to the sensed input signal. However, a region of the electronic apparatus ED which senses an external input is not limited to the front surface of the electronic apparatus ED, and may vary according to a design of the electronic apparatus ED. For example, the electronic apparatus ED may sense a user's input applied to a side surface and/or a rear surface of the electronic apparatus ED.

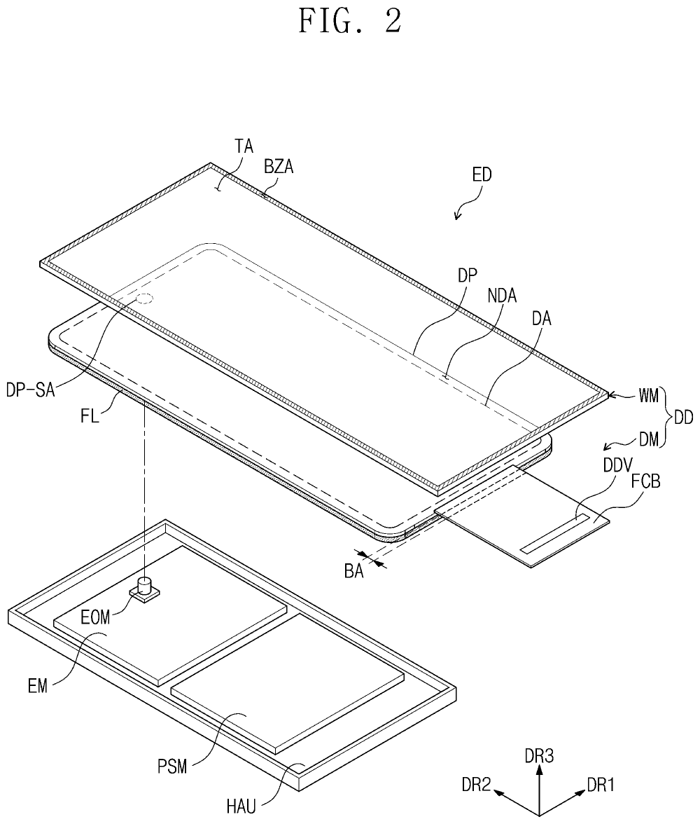

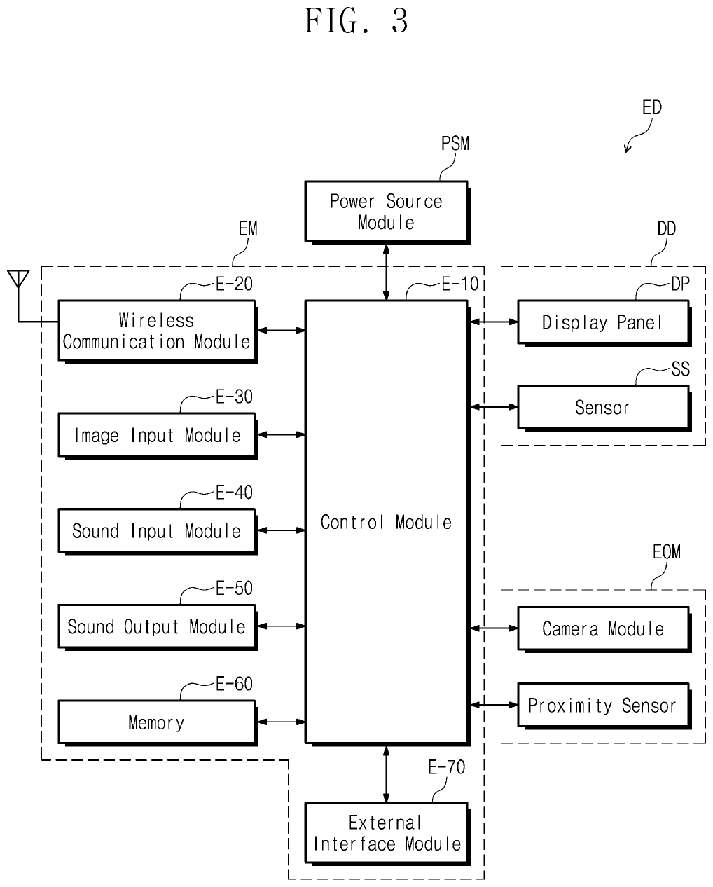

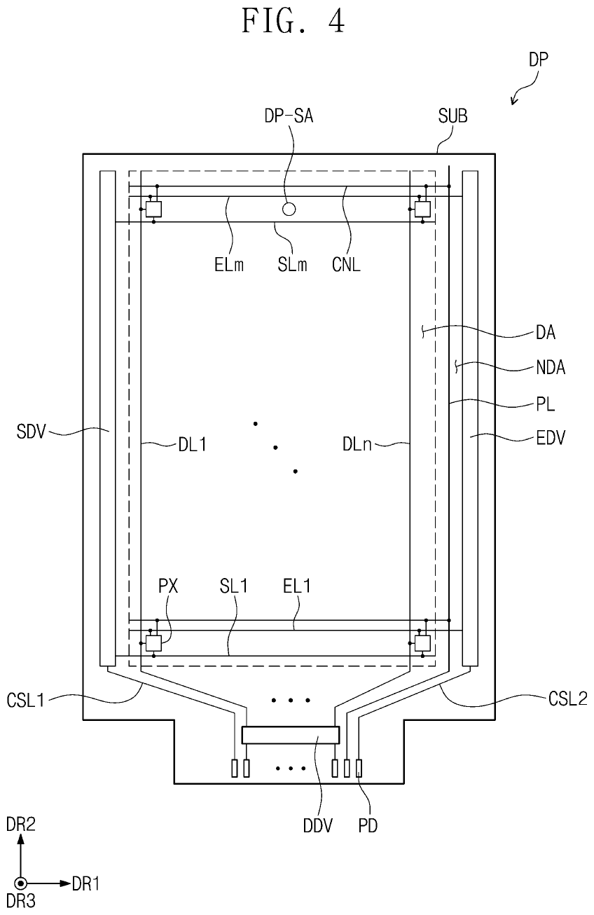

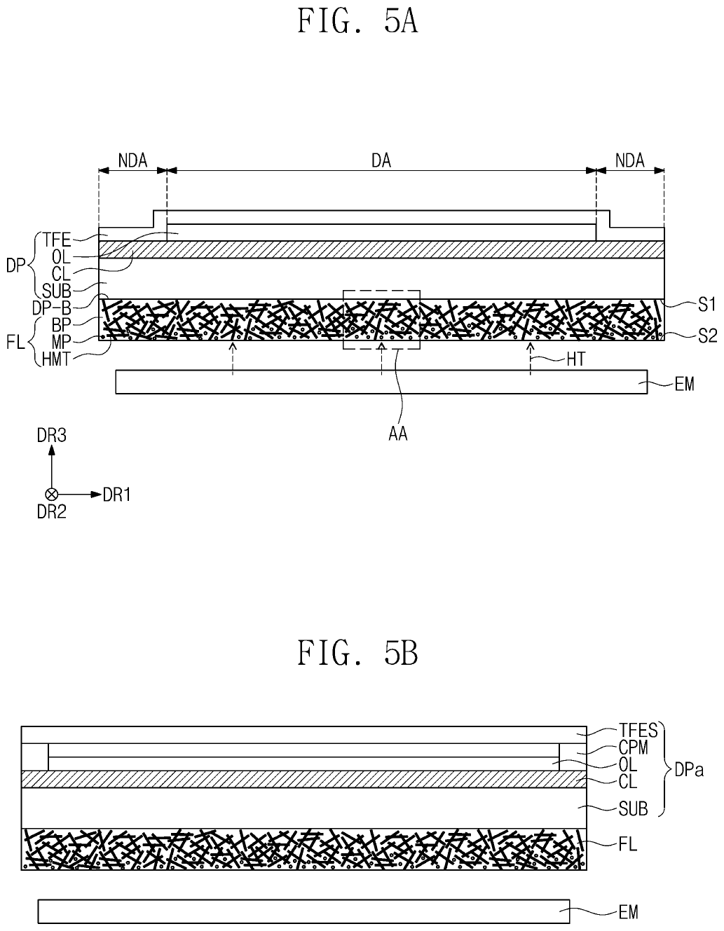

FIG. 2 is an exploded perspective view of an electronic apparatus according to an embodiment. FIG. 3 is a block diagram of an electronic apparatus according to an embodiment.

In an embodiment and referring to FIG. 2 and FIG. 3, the electronic apparatus ED may include a display device DD, an electronic module EM, an electronic optical module EOM, a power source module PSM, and a housing HAU.

In an embodiment, the display device DD may generate an image, and may sense an external input. The display device DD may include a window WM and a display module DM. The display module DM may include at least a display panel DP, and may further include at least one component disposed on the display panel DP. FIG. 2 schematically illustrates only the display panel DP in a stacked structure of the display module DM, but an embodiment of the display module DM is not limited thereto.

In an embodiment, the window WM may be disposed on the display module DM. The window WM may cover a front surface of the display module DM, and may protect the display module DM from external impacts and scratches. The window WM may be coupled to the display module DM through an adhesive layer.

In an embodiment, the window WM may include an optically transparent insulation material. For example, the window WM may include a glass a film and/or a synthetic resin film as a base film. The window WM may have a single-layered structure or a multi-layered structure. For example, the window WM may include a plurality of synthetic resin films bonded with an adhesive, or a glass film and a synthetic resin film bonded with an adhesive. The window WM may further include a functional layer such as an anti-fingerprint layer, a phase control layer, and/or a hard coating layer disposed on the base film.

In an embodiment, a front surface of the window WM may correspond to the front surface of electronic apparatus ED. The front surface of the window WM may include a transmissive region TA and/or a bezel region BZA.

In an embodiment, the transmissive region TA may be an optically transparent region. The transmissive region TA may transmit an image provided by the display panel DP, and a user may visually recognize the image through the transmissive region TA. In an embodiment, the transmissive region TA is illustrated as being in a quadrangular shape, but the transmissive region TA may have various shapes, and is not limited to any one embodiment.

In an embodiment, the bezel region BZA may be adjacent to the transmissive region TA. The shape of the transmissive region TA may be substantially defined by the bezel region BZA. For example, the bezel region BZA may be disposed on an outer side of the transmissive region TA to surround the transmissive region TA. However, this is only exemplarily illustrated, and the bezel region BZA may be adjacent to only one side of the transmissive region TA, or may be omitted. In addition, in an embodiment, the bezel region BZA may be disposed on a side surface of the electronic apparatus ED, not on the front surface thereof.

In an embodiment, the bezel region BZA may be a region having a lower light transmittance than the transmissive region TA. The bezel region BZA may correspond to a region in which a material having a predetermined color is printed. The bezel region BZA prevents the transmittance of light, and thus may prevent a component of the display module DM overlapping the bezel region BA from being be visually recognized from the outside.

In an embodiment, the display panel DP may be disposed between the window WM and the housing HAU. The display panel DP may display an image according to an electrical signal. The display panel DP according to an embodiment may be a light emitting type display panel, but is not limited thereto. For example, the display panel DP may be an organic light emitting display panel, an inorganic light emitting display panel, and/or a quantum dot light emitting display panel. A light emitting layer of the organic light emitting display panel may include an organic light emitting material, and a light emitting layer of the inorganic light emitting display panel may include an inorganic light emitting material. A light emitting layer of the quantum dot light emitting display panel may include a quantum dot, a quantum load, and/or the like. Hereinafter, the display panel DP will be described as an organic light emitting display panel.

In an embodiment, the display panel DP may include a display region DA and a non-display region NDA. The display region DA may be a region in which a light emitting element is disposed. The light emitting element may generate light in correspondence to an electrical signal, and may output an image through the display region DA. For example, the light emitting element may be a light emitting diode, but the embodiment of the inventive concept is not necessarily limited thereto. The display region DA may overlap at least a portion of the transmissive region TA.

In an embodiment, the display panel DP may include a sensing region DP-SA, and may correspond to the sensing region of the electronic apparatus ED described above. That is, the sensing region DP-SA may be a region having a relatively high optical signal transmittance in the display region DA. The sensing region DP-SA may be defined in the display region DA. However, the embodiment is not limited thereto, and a portion of the sensing region DP-SA may be defined in the non-display region NDA.

In an embodiment, the light emitting element may be disposed in the sensing region DP-SA. The density of light emitting elements disposed in the sensing region DP-SA may be less than the density of light emitting elements disposed in other regions located apart from the sensing region DP-SA in the display region DA. That is, the sensing region DP-SA may be a region having relatively low resolution than other regions of the display region DA.

In an embodiment, the non-display region NDA may be adjacent to the display region DA. For example, the non-display region NDA may surround the display region DA. However, the embodiment is not limited thereto, and the non-display region NDA may be defined in various shapes. The non-display region NDA may be a region in which a driving circuit for driving a light emitting element disposed in the display region DA, signal lines for providing an electrical signal to the light emitting element, and/or pads are disposed. The non-display region NDA may overlap at least a portion of the bezel region BZA, and components disposed in the non-display region NDA may be prevented from being visually recognized from the outside by the bezel region BZA.

In an embodiment, the electronic apparatus ED may include a flexible circuit board FCB electrically connected to the display panel DP. The flexible circuit board FCB may be disposed in the non-display region NDA of the display panel DP to be coupled to the display panel DP. The flexible circuit board FCB may be connected to a main circuit board. The main circuit board may be one electronic component constituting the electronic module EM. A partial region of the flexible circuit board FCB may be provided as a bending region BA. The bending region BA may be bent around a bending axis parallel to the first direction DR1. Due to the bending of the bending region BA, the flexible circuit board FCB may overlap a portion of the display panel DP on a plane.

In an embodiment, the flexible circuit board FCB may include a data driver DDV. The data driver DDV may include a data driving circuit for driving a pixel in the display region DA. In an embodiment, the data driver DDV may be mounted on the flexible printed board FCB. However, the embodiment is not limited thereto, and the data driver DDV may be provided in the form of an integrated circuit chip mounted in the non-display region NDA.

In an embodiment, the window WM and the housing HAU may be coupled to each other to configure the appearance of the electronic apparatus ED. The display module DM, the electronic module EM, and the power source module PSM may be accommodated in an inner space formed by the coupling of the window WM and the housing HAU.

In an embodiment, the housing HAU may include a material having relatively high rigidity. For example, the housing HAU may include glass, plastic, and/or a metal, and/or may include a plurality of frames and/or plates composed of a combination thereof. The housing HAU may protect components of the electronic apparatus ED, which are accommodated in the housing HAU, by either absorbing an impact applied from the outside or preventing foreign substances/moisture and/or the like from penetrating from the outside.

In an embodiment and referring to FIG. 3, the display device DD may include the display panel DP and a sensor SS. The sensor SS may include at least one of an input sensor, an antenna sensor, and/or a fingerprint sensor.

In an embodiment, the electronic module EM may include a control module E-10, a wireless communication module E-20, an image input module E-30, a sound input module E-40, a sound output module E-50, a memory E-60, an external interface module E-70, and/or the like. The electronic module EM may include a main circuit board, and modules included in the electronic module EM may be mounted on the main circuit board, and/or may be electrically connected to the main circuit board through a flexible circuit board. The electronic module EM may be electrically connected to the power source module PSM.

In an embodiment, the control module E-10 may control the overall operation of the electronic apparatus ED. For example, the control module E-10 may activate and/or deactivate the display device DD in accordance with a user input. The control module E-10 may control the image input module E-30, the sound input module E-40, the sound output module E-50, and/or the like in accordance with the user input. The control module E-10 may include at least one microprocessor.

In an embodiment, the wireless communication module E-20 may transmit/receive wireless signals with other terminals using Bluetooth and/or a Wi-Fi line. The wireless communication module E-20 may transmit/receive voice signals using a general communication line. The wireless communication module E-20 may include a plurality of antenna modules.

In an embodiment, the image input module E-30 may process an image signal and/or convert the processed image signal into image data displayable on the display device DD. The sound input module E-40 may receive an external sound signal through a microphone in a recording mode, a voice recognition mode, and/or the like and/or convert the received external sound signal into electrical voice data. The sound output module E-50 may convert sound data received from the wireless communication module E-20 and/or sound data stored in the memory E-60 and output the converted sound data to the outside.

In an embodiment, the external interface module E-70 may serve as an interface to be connected to an external charger, a wired/wireless data port, a card socket module (e.g., a memory card and a SIM/UIM card), and/or the like.

In an embodiment, the power source module PSM may supply power necessary for the overall operation of the electronic apparatus ED. For example, the power source module PSM may include a typical battery device.

In an embodiment and referring to FIG. 2 together, the electronic optical module EOM overlaps the sensing region DP-SA, and may be disposed below the display panel DP. The electronic optical module EOM may be an electronic component which receives an optical signal provided from the outside through the sensing region DP-SA, and/or which outputs an optical signal to the outside. For example, the electronic optical module EOM may include a camera module and/or a proximity sensor. The camera module may be a module for capturing an external image through the sensing region DP-SA. The proximity sensor may be a sensor for measuring a distance between an object and the electronic apparatus ED by using information received through the sensing region DP-SA. However, the embodiment of the electronic optical module EOM is not limited thereto, and may further include a sensor for recognizing a part of a user's body (e.g., a fingerprint, an iris, and/or a face), and/or a small lamp for outputting light.

In an embodiment and referring to FIG. 2, the electronic apparatus ED may include a functional layer FL disposed on a rear surface of the display panel DP. The functional layer FL may be directly formed on the rear surface of the display panel DP. That is, the functional layer FL may be coupled to a component defining the rear surface of the display panel DP without a separate adhesive layer. The functional layer FL may be provided as a single layer and perform a heat dissipation function. That is, electronic components such as the electronic module EM, the power source module PSM, the electronic optical module EOM, and the flexible circuit board FCB disposed on the rear surface of the display panel DP may generate heat, and the functional layer FL may prevent the heat generated from the electronic components from being transmitted to the display panel DP.

FIG. 4 is a plan view of the display panel DP according to an embodiment.

In an embodiment and referring to FIG. 4, the display panel DP may include a base substrate SUB, pixels PX, signal lines SL1 to SLm, DL1 to DLn, EL1 to ELm, CSL1, CSL2, PL, and CNL electrically connected to the pixels PX, a scan driver SDV, a data driver DDV, and an emission driver EDV.

In an embodiment, the base substrate SUB may provide a base surface on which elements and lines of the display panel DP are disposed on a plane parallel to each of the first direction DR1 and the second direction DR2. The base substrate SUB may include a display region DA and a non-display region NDA respectively corresponding to the display region DA and the non-display region NDA of the display panel DP described above.

In an embodiment, the pixels PX may be disposed in the display region DA to display images. The non-display region NDA may be adjacent to the display region DA, and/or may be a region in which an image is not displayed. In the non-display region NDA, the scan driver SDV, the data driver DDV, and the emission driver EDV for driving the pixels PX may be disposed. However, in order to reduce the area of the non-display region NDA, at least one of the scan driver SDV, the data driver DDV, and/or the emission driver EDV may be disposed in the display region DA.

In an embodiment, each of the pixels PX may include a light emitting element, transistors (e.g., a switching transistor, a driving transistor, etc.) connected to the light emitting element, and/or a pixel driving circuit composed of at least one capacitor. The pixels PX may emit light in correspondence to an electrical signal applied to each of the pixels PX to display an image in the display region DA. Some of the pixels PX may include a transistor disposed in the non-display region NDA, and are not limited to any one embodiment.

In an embodiment, the signal lines SL1 to SLm, DL1 to DLn, EL1 to ELm, CSL1, CSL2, PL, and CNL may include scan lines SL1 to SLm, data lines DL1 to DLn, emission lines EL1 to ELm, first and second control lines CSL1 and CSL2, a power line PL, and connection lines CNL. Here, m and n represent natural numbers.

In an embodiment, the data lines DL1 to DLn may cross the scan lines SL1 to SLm and the light emission lines EL1 to ELm while being insulated therefrom. For example, the scan lines SL1 to SLm may be extended in the first direction DR1 to be connected to the scan driver SDV. The data lines DL1 to DLn may be extended in the second direction DR2 to be connected to the data driver DDV. The emission lines EL1 to ELm may be extended in the first direction DR1 to be connected to the emission driver EDV.

In an embodiment, the power line PL may be extended in the second direction DR2 to be disposed in the non-display region NDA. In an embodiment, the power line PL may be disposed between the display region DA and the emission driver EDV. However, the position at which the power line PL is disposed is not limited thereto.

In an embodiment, the connection lines CNL may be extended in the first direction DR1, and may be arranged along the second direction DR2 to be connected to the power line PL and the pixels PX. Each of the connection lines CNL may be disposed on a layer different from the layer on which the power line PL is disposed, and/or be electrically connected to the power line PL through a contact hole. However, the embodiment is not limited thereto, and the connection lines CNL may be formed as a single body with the power line PL on the same layer. A power voltage applied to the power line PL may be applied to the pixels PX through the connection lines CNL.

In an embodiment, a first control line CSL1 may be connected to the scan driver SDV. A second control line CSL2 may be connected to the emission driver EDV.

In an embodiment, pads PD may be disposed adjacent to a lower end of the non-display region NDA. The pads PD may be disposed more adjacent to the lower end of the display panel DP than the data driver DDV. The pads PD may be disposed to be spaced apart along the first direction DR1. Each of the pads PD may be connected to a corresponding signal line among the signal lines. For example, the power line PL, the first control line CSL1, and the second control line CSL2 may be electrically connected to the pads PD, and the data lines DL1 to DLn may be electrically connected to corresponding pads PD through the data driver DDV, respectively. The pads PD may be a portion to which the flexible circuit board FCB (see FIG. 2) described above is electrically connected. Accordingly, an electrical signal provided from the flexible circuit board FCB (see FIG. 2) may be transmitted to the display panel DP through the pads PD.

In an embodiment, the scan driver SDV may generate scan signals in response to a scan control signal. The scan signals may be applied to the pixels PX through the scan lines SL1 to SLm. The data driver DDV may generate data voltages corresponding to image signals in response to a data control signal. The data voltages may be applied to the pixels PX through the data lines DL1 to DLn. The emission driver EDV may generate emission signals in response to an emission control signal. The emission signals may be applied to the pixels PX through the emission lines EL1 to ELm.

In an embodiment, the pixels PX may be provided with the data voltages in response to the scan signals. The pixels PX may generate an image by emitting light of luminance corresponding to the data voltages in response to the emission signals. The emission duration of the pixels PX may be controlled by the emission signals.

FIG. 5A is a cross-sectional view of a portion of an electronic apparatus according to an embodiment. Specifically, FIG. 5A is a cross-sectional view of the display panel DP and the functional layer FL according to an embodiment.

In an embodiment and referring to FIG. 5A, the display panel DP may include the base substrate SUB, a circuit layer CL, a display element layer OL, and an encapsulation layer TFE. The display panel DP may include a rear surface DP-B facing the functional layer FL. The rear surface DP-B of the display panel DP may substantially correspond to a rear surface of the base substrate SUB, and hereinafter, the rear surface of the base substrate SUB will be given the same reference numeral as the rear surface DP-B of the display panel DP.

In an embodiment, the base substrate SUB may provide a base surface on which the circuit layer CL is disposed. The base substrate SUB may be a rigid substrate, or a flexible substrate capable of bending, folding, rolling, and/or the like. The base substrate SUB may be a glass substrate, a metal substrate, a polymer substrate, and/or the like. However, the embodiment is not limited thereto, and the base substrate SUB may include an inorganic layer, a synthetic resin layer, and/or a composite material layer.

In an embodiment, the base substrate SUB may have a multi-layered structure. For example, the base substrate SUB may include synthetic resin layers and/or a multi-layered or single inorganic layer disposed between the synthetic resin layers. Each of the synthetic resin layers may include an acrylic resin, a methacrylic resin, polyisoprene, a vinyl-based resin, an epoxy-based resin, a urethane-based resin, a cellulose-based resin, a siloxane-based resin, a polyamide-based resin, a perylene-based resin, and/or the like, but the material of the synthetic resin layers is not limited thereto.

In an embodiment, the circuit layer CL may be disposed on the base substrate SUB. The circuit layer CL may include at least one insulation layer, a semiconductor pattern, and/or a conductive pattern. The insulation layer, the semiconductor pattern, and/or the conductive pattern included in the circuit layer CL may form driving elements, signal lines, and/or pads in the circuit layer CL.

In an embodiment, the display element layer OL may be disposed on the circuit layer CL. The display element layer OL may include emission elements disposed in the display region DA. The light emitting elements may include an organic light emitting element, an inorganic light emitting element, a micro-LED, a nano-LED, and/or the like, and are not particularly limited. The light emitting elements of the display element layer OL may be electrically connected to the driving elements of the circuit layer CL, and may generate light in the display region DA according to a signal provided by the driving elements.

In an embodiment, the encapsulation layer TFE may be disposed on the display element layer OL, and/or encapsulate the light emitting elements. The encapsulation layer TFE may include at least one thin film to enhance optical efficiency of the display element layer OL, and/or to protect the display element layer OL. The encapsulation layer TFE may include at least one of an inorganic film or an organic film. In an embodiment, the encapsulation layer TFE may include a stacking structure of inorganic films and an organic film disposed between the inorganic films, but is not particularly limited thereto. The inorganic film of the encapsulation layer TFE may protect a light emitting element from moisture/oxygen. The organic film of the encapsulation layer TFE may protect a light emitting element from foreign substances such as dust particles.

In an embodiment, a sensor layer may be disposed on the display panel DP. The sensor layer may be formed on the display panel DP through a continuous process. In this case, the sensor layer may be directly disposed on the display panel DP without a separate adhesive layer. However, the embodiment is not necessarily limited thereto, and the sensor layer may be coupled on the display panel DP through an adhesive layer.

In an embodiment, the sensor layer may include at least one of an input sensor, an antenna sensor, or a fingerprint sensor. For example, the sensor layer may include an input sensor, wherein the input sensor may sense an external input and/or provide an input signal including information on the external input such that the display panel DP may generate an image corresponding to the external input. The input sensor may be driven in various ways, such as a capacitive method, a resistive method, an infrared method, a sonic method, and/or a pressure method, but is not limited to any one thereof. On the sensor layer, an anti-reflection layer and/or the like may be further disposed.

In an embodiment, the functional layer FL may be disposed on the rear surface DP-B of the display panel DP. For example, the functional layer FL may be directly formed on the rear surface DP-B of the display panel DP. The functional layer FL may include a base portion BP, heat dissipation materials HMT and metal particles MP which are distributed inside the base portion BP.

In an embodiment, the base portion BP may contact the rear surface DP-B of the display panel DP. For example, the base portion BP may contact the base substrate SUB of the display panel DP. That is, the base portion BP may be coupled to the base substrate SUB without a separate adhesive layer disposed between the base substrate SUB and the base portion BP.

In an embodiment, the base portion BP may include a first surface S1 facing the rear surface DP-B of the display panel DP and a second surface S2 opposite to the first surface S1. The first surface S1 of the base portion BP may correspond to an upper surface of the functional layer FL, and may contact the rear surface DP-B of the display panel DP. The second surface S2 of the base portion BP may correspond to a lower surface of the functional layer FL, and may be spaced apart from the rear surface DP-B of the display panel DP.

In an embodiment, the first surface S1 of the base portion BP may substantially face the rear surface DP-B of the display panel DP in the third direction DR3. The second surface S2 of the base portion BP may be substantially spaced apart from the rear surface DP-B of the display panel DP in the third direction DR3.

In an embodiment, electronic components such as the electronic module EM or the power supply module PSM (see FIG. 2) disposed below the functional layer FL may generate heat HT. However, since the functional layer FL is disposed between the display panel DP and the electronic components (e.g., the electronic module EM), the heat HT generated from the electronic components may be dissipated so as not to be transmitted to the display panel DP.

According to an embodiment, the functional layer FL may be provided as a single layer rather than a plurality of functional layers stacked in the third direction DR3. In addition to performing heat dissipation, the functional layer FL may protect the display panel DP from external impacts and/or interference transmitted toward the rear surface DP-B of the display panel DP. For example, the functional layer FL may play a role in impact absorption, light blocking, electromagnetic wave blocking, and/or the like in addition to heat dissipation. Specifically, the functional layer FL may block or absorb electromagnetic waves generated from the electronic components disposed on the rear surface DP-B of the display panel DP to prevent the electromagnetic waves from affecting the display panel DP as noise. In addition, the functional layer FL may block light emitted to the rear surface DP-B of the display panel DP to solve the problem of the electronic components disposed on the rear surface DP-B of the display panel DP being visually recognized or seen from the outside.

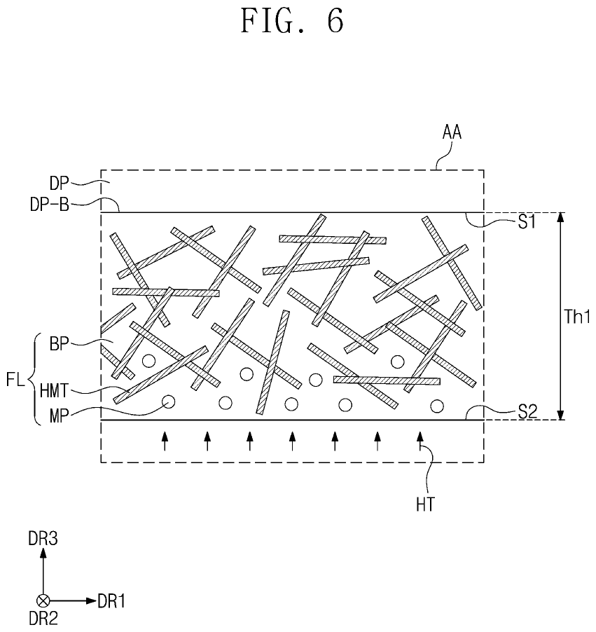

In an embodiment, since the functional layer FL may protect the display panel DP from external factors such as heat, impacts, and/or electromagnetic waves transmitted to the display panel DP, the reliability of the display panel DP and the electronic apparatus ED may be improved. In addition, since the functional layer FL has a single-layered structure and is directly formed on the rear surface DP-B of the display panel DP, the display device DD (see FIG. 1) and the electronic apparatus ED (see FIG. 1) in which the functional layer FL is disposed may be provided to be thin, and at the same time, the reliability of the display panel DP may be improved. The configuration of the functional layer FL will be described in detail with reference to FIG. 6.

FIG. 5B is a cross-sectional view of a display panel according to an embodiment.

Referring to FIG. 5B, a display panel DPa according to an embodiment may include a base substrate SUB, a circuit layer CL, a display element layer OL, an encapsulation substrate TFES, and/or a coupling member CPM.

In an embodiment, each of the base substrate SUB and the encapsulation substrate TFES may be a glass substrate, a metal substrate, a polymer substrate, and/or the like, but is not particularly limited thereto.

In an embodiment, the coupling member CPM may be disposed between the base substrate SUB and encapsulation substrate TFES. The coupling member CPM may couple the encapsulation substrate TFES to the base substrate SUB and/or the circuit layer CL. The coupling member CPM may include an inorganic substance and/or an organic substance. For example, the inorganic material may include frit seal, and/or the organic material may include a photo-curable resin and/or a photo-plastic resin. However, the material constituting the coupling member CPM is not limited to the above examples.

In an embodiment, although not illustrated, a sensor layer may be directly disposed on the encapsulation substrate TFES. Being directly disposed may mean that a third component is not disposed between the sensor layer and the encapsulation substrate TFES. That is, a separate adhesive member may not be disposed between the sensor layer and the display panel DPa. However, the embodiment is not limited thereto, and an adhesive member may be further disposed between the sensor layer and the display panel DPa.

In an embodiment, FIG. 6 is an enlarged view of a region AA illustrated in FIG. 5A.

In an embodiment and referring to FIG. 6, the functional layer FL may include the base portion BP, the heat dissipation materials HMP and/or the metal particles MP which are distributed inside of the base portion BP.

According to an embodiment, the base portion BP may include styrene-butadiene rubber. The styrene-butadiene rubber is a synthetic rubber which is a copolymer of styrene and butadiene. In general, the styrene-butadiene rubber has about 23% styrene, and when the content of styrene is increased, the repulsive elasticity decreases, and the glass transition point of vulcanized rubber increases. The styrene-butadiene rubber has excellent flexibility, abrasion resistance, repulsive elasticity, and impact resistance. Therefore, since the base portion BP comprises styrene-butadiene rubber, the flexibility, abrasion resistance, repulsive elasticity, and impact resistance may be excellent. Since the base portion BP has flexibility, the functional layer FL may also be applied to the flexible electronic apparatus ED (see FIG. 1). In addition, since the base portion BP has impact resistance, an impact transmitted from the outside toward the display panel DP may be absorbed. As a result, even without a separate impact absorption layer disposed on the rear surface DP-B of the display panel DP, the functional layer FL may protect the display panel DP, and/or the electronic apparatus ED may have a simplified stacking structure, and thus, may be provided to be thin.

According to an embodiment, the heat dissipation materials HMT may include a carbon-based heat dissipation material. For example, the heat dissipation materials HMT may include graphene, graphite, and/or carbon nanotubes as the carbon-based heat dissipation material. The heat dissipation materials HMT may have a thin-film shape and/or a rod shape. Since the heat dissipation materials HMT have a thin-film shape and/or a rod shape, pores may be formed between the heat dissipation materials HMT. The heat dissipation materials HMT may be uniformly distributed inside the base portion BP. Specifically, the heat dissipation materials HMT may be uniformly distributed at high density on the first, second and/or third directions DR1, DR2, and DR3, respectively, inside the base portion BP. Since the heat dissipation materials HMT may be uniformly distributed at high density inside the base portion BP, the occurrence of pores present between the heat dissipation materials HMT may be reduced, and/or the thickness of the functional layer FL may be reduced.

A thickness Th1 of the functional layer FL according to an embodiment may be about 100 μm to about 350 μm. For example, the thickness Th1 of the functional layer FL may be about 200 μm. The thermal diffusion coefficient of a material increases as the thickness of the material decreases and the density of heat dissipation materials HMT inside the material increases. Since the functional layer FL is thin, and the heat dissipation materials HMP are uniformly distributed at high density inside the base portion BP, the functional layer FL according to an embodiment may have a high thermal diffusion coefficient. Specifically, the thermal diffusion coefficient of the functional layer FL may be about 43 mm²/s.

In an embodiment, the electronic components such as the electronic module EM and/or the power source module PSM (see FIG. 2) disposed below the display panel DP may generate the heat HT, and the heat HT generated from the electronic components may be diffused toward the display panel DP. However, the functional layer FL may have a high thermal diffusion coefficient by including the heat dissipation materials HMT uniformly distributed inside the base portion BP and having a high specific gravity in the functional layer FL. Since the functional layer FL has a high thermal diffusion coefficient, the heat HT generated from the electronic components may be efficiently dissipated so as not to be transmitted to the display panel DP. As a result, the reliable electronic apparatus ED (see FIG. 1) may be provided.

The heat dissipation materials HMT according to an embodiment may have light blocking properties. For example, the heat dissipation materials HMT may include a black pigment and/or a black dye as a carbon-based heat dissipation material, and as a result, may have a light blocking function. Since the heat dissipation materials HMT have the light blocking function, the functional layer FL may block light emitted to the rear surface DP-B of the display panel DP. Therefore, the functional layer FL may prevent the electronic components disposed below the display panel DP from being visually recognized and/or seen from the outside due to the light emitted to the rear surface DP-B of the display panel DP.

In an embodiment, the metal particles MP may each have a predetermined size and be dispersed in the base part BP, not in the form of a thin film. The metal particles MPs may each include a material having conductivity. For example, the metal particles MP may include a metal material such as copper (Cu) and/or silver (Ag).

In an embodiment, the metal particles MP may be densely distributed in a specific region of the base portion BP. Specifically, the metal particles MP may be densely distributed in a specific region of the base portion BP spaced apart from the display panel DP. The metal particles MP may be densely distributed in a lower portion of the base portion BP, and may not be substantially distributed in an upper portion thereof. Therefore, based on the same volume, the density of the metal particles MP in the lower portion of the base portion BP may be greater than the density of the metal particles MP in the upper portion of the base portion BP.

In an embodiment, the metal particles MP may be spaced apart from the first surface S1 of the base portion BP, and the metal particles MP may not be dispersed in a region adjacent to the first surface S1 of the base portion BP. The metal particles MP may be more densely distributed in a region closer to the second surface S2 than in a region closer to the first surface S1 of the base BP. Therefore, the metal particles MP may be dispersed in a region adjacent to the second surface S2 of the base portion BP, and the density of the metal particles MP may be relatively greater in the region adjacent to the second surface S2 than in the region adjacent to the first surface S1.

According to an embodiment, since the metal particles MP are concentrated in the lower portion of the base portion BP, specifically, in the region adjacent to the second surface S2, electromagnetic waves generated from the electronic components may be blocked by the metal particles MP. Since the metal particles MP are not distributed in the upper portion of the base portion BP, specifically, in the region adjacent to the second surface S2, the upper surface of the functional layer FL corresponding to the first surface S1 of the base portion BP may not be conductive. Since the metal particles MP are densely distributed in the lower portion of the base portion BP, the lower surface of the functional layer FL corresponding to the second surface S2 of the base portion BP may be conductive. That is, since the metal particles MP are densely distributed in the lower portion of the base portion BP, the functional layer FL may have conductive properties similar to those of a case in which a conductive layer is disposed below the base portion BP.

In an embodiment, since a lower portion of the functional layer FL has conductivity, electromagnetic waves generated from electronic components such as the electronic module EM (see FIG. 2), the power source module PSM (see FIG. 2), and/or the electronic optical module EOM (see FIG. 2) disposed below the lower surface of the functional layer FL may be blocked. Therefore, the functional layer FL may prevent the electromagnetic waves generated from the electronic components disposed below the functional layer FL from being transmitted to the display panel DP, and as a result, noise may be prevented from being generated in an image displayed on the display panel. In addition, even without a separate electromagnetic wave blocking layer disposed on the rear surface DP-B of the display panel DP, the functional layer FL has the effect of blocking electromagnetic waves, and thus may protect the display panel DP from the electromagnetic waves generated from the electronic components, and the electronic apparatus ED may have a simplified stacking structure.

In addition, in an embodiment, since the lower portion of the functional layer FL has conductivity, an electrostatic pass may be formed in the lower portion of the functional layer FL. Therefore, when static electricity is generated, the functional layer FL may discharge the static electricity to protect electronic components of the flexible circuit board FCB (see FIG. 2) disposed adjacent to the lower portion of the functional layer FL, and/or the data driver DDV (see FIG. 2), and/or the like. In addition, even without a separate conductive layer for preventing static electricity disposed on the rear surface DP-B of the display panel DP, the functional layer FL has an anti-static effect, and thus may protect the electronic components from static electricity, and the electronic apparatus ED may have a simplified stacking structure.

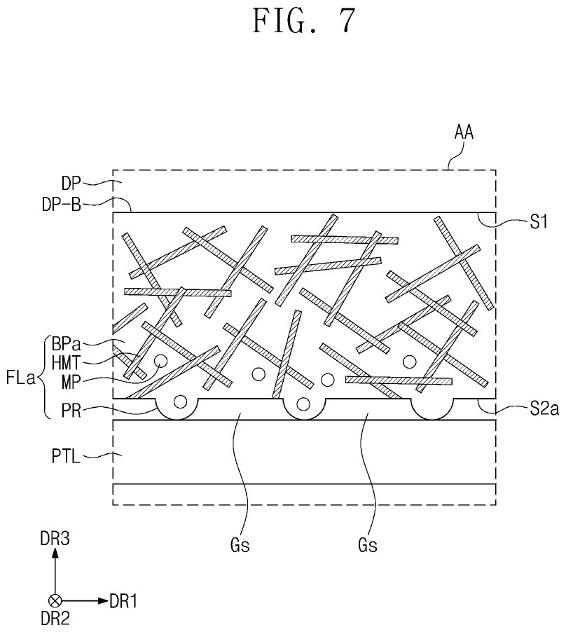

FIG. 7 is an enlarged, cross-sectional view of a functional layer according to an embodiment. Hereinafter, redundant descriptions of components of a functional layer FLa will be omitted.

In an embodiment and referring to FIG. 7, a protective layer PTL may be disposed in a lower portion of the functional layer FLa. The protective layer PTL may be disposed below the functional layer FLa to protect the functional layer FLa. The protective layer PTL may include a flexible plastic material such as polyimide and/or polyethylene terephthalate. A protective film PF may be a colored film having low light transmittance.

In an embodiment, a base portion BPa may include a first surface S1 facing the rear surface DP-B of the display panel DP and a second surface S2a opposite to the first surface S1. According to an embodiment of the inventive concept, the functional layer FLa may further include a plurality of protruded portions PR protruding from the second surface S2a, when compared to the functional layer FL illustrated in FIG. 6. The plurality of protruded portions PR may be arranged at a predetermined interval along the first direction DR1. The protective layer PTL disposed in the lower portion of the functional layer FLa may be in direct contact with the plurality of protruded portions PR. Since the plurality of protruded portions PR are in contact with the protective layer PTL, a gap Gs may be formed between the second surface S2a and the protective layer PTL.

In an embodiment, the plurality of protruded portions PR may be composed of the same material as the material of the base portion BPa. Specifically, the plurality of protruded portions PR may include styrene-butadiene rubber. Since the functional layer FLa includes the plurality of protruded portions PR, and the gap Gs is formed between the second surface S2a and the protective layer PTL, an impact applied to the display panel DP disposed on the functional layer FLa may be absorbed. In addition, since heat dissipation performance improves as a surface area capable of dissipating heat increases, due to the plurality of protruded portions PR, the area of the second surface S2a of the functional layer FLa is greater than the area of the second surface S2 of the functional layer FL illustrated in FIG. 6, so that the heat dissipation performance of the functional layer FLa may be improved.

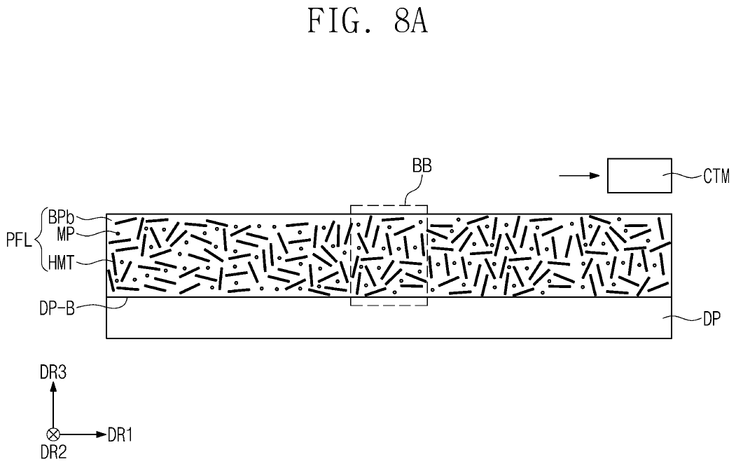

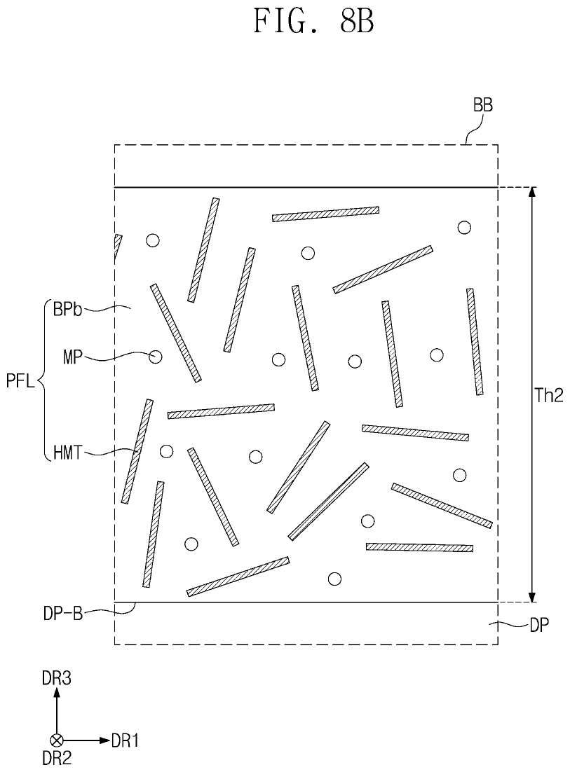

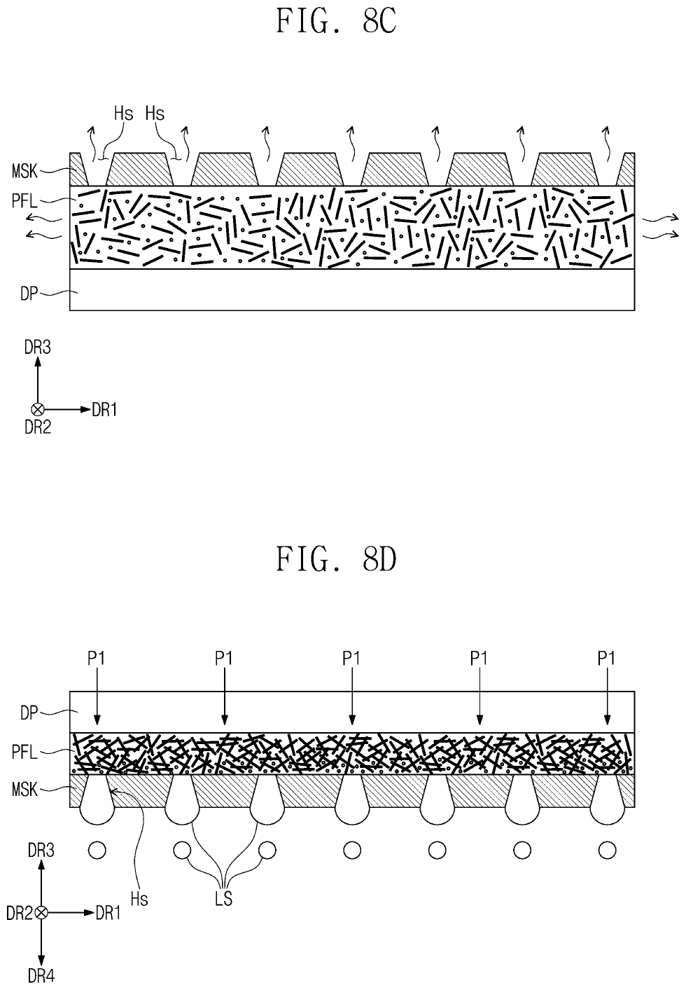

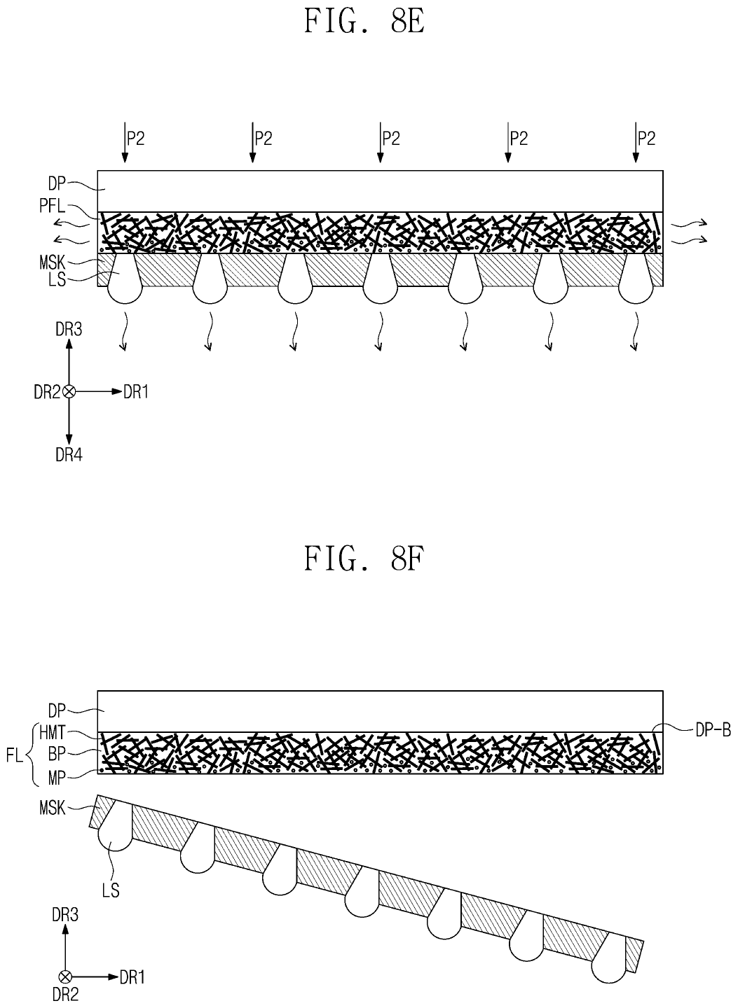

FIG. 8A to FIG. 8F are cross-sectional views of some steps of a method for manufacturing an electronic apparatus according to an embodiment.

In an embodiment, FIG. 8A is a cross-sectional view illustrating a step of forming a preliminary functional layer PFL on the rear surface DP-B of the display panel DP. FIG. 8B is an enlarged view of a region BB illustrated in FIG. 8A.

In an embodiment and referring to FIG. 8A, coating a resin on the back surface DP-B of the display panel DP to form the preliminary functional layer PFL may be performed. The resin may include a base portion BPb, heat dissipation materials HMT, and metal particles MP. A method for coating the resin may be performed by directly coating the resin on the back surface DP-B of the display panel DP in the first and second directions DR1 and DR2, respectively, using a coating device CTM. At this time, the resin may be in a liquid state before being cured. That is, the preliminary functional layer PFL formed by coating the resin may be a liquid coating layer.

In an embodiment and referring to FIG. 8A and FIG. 8B, the preliminary functional layer PFL may include the base portion BPb, the heat dissipation materials HMT, and the metal particles MP. The heat dissipation materials HMT and the metal particles MP may be uniformly distributed inside the base portion BPb. A thickness Th2 of the preliminary functional layer PFL may be different from the thickness Th1 of the functional layer FL illustrated in FIG. 6. Specifically, the thickness Th2 of the preliminary functional layer PFL may be greater than the thickness Th1 of the functional layer FL. Since the thickness Th2 of the preliminary functional layer PFL is formed to be greater than the thickness Th1 of the functional layer FL, the density of the heat dissipation materials HMT and the metal particles MP distributed inside the base portion BPb may be small. Specifically, the density of the heat dissipation materials HMT and the metal particles MP distributed inside the base portion BPb may be smaller than the density of the heat dissipation materials HMT and the metal particles MP distributed inside the base portion BP illustrated in FIG. 6.

In an embodiment, FIG. 8C is a cross-sectional view illustrating the step of disposing a mask MSK on the preliminary functional layer PFL and pre-curing the preliminary functional layer PFL.

In an embodiment and referring to FIG. 8C, the mask MSK including a plurality of holes Hs may be disposed on the preliminary functional layer PFL. After the mask MSK is disposed, the pre-curing of the preliminary functional layer PFL may be performed. A process of pre-curing the preliminary functional layer PFL may include a process of curing the preliminary functional layer PFL through either thermal-curing or UV-curing the preliminary functional layer PFL inside a sealed chamber. According to an embodiment, the process of pre-curing the preliminary functional layer PFL may be the process of thermal-curing the preliminary functional layer PFL. The pre-curing process may be performed after the mask MSK is disposed on the preliminary functional layer PFL, but is not limited thereto, and may be performed before the mask MSK is disposed on the preliminary functional layer PFL. Since the pre-curing process is performed by thermal-curing, even if the mask MSK is disposed on the preliminary functional layer PFL, the curing of the preliminary functional layer PFL may not be affected thereby. The preliminary functional layer PFL may have adhesive force due to the pre-curing.

In an embodiment, FIG. 8D is a cross-sectional view illustrating a step of inverting the display panel DP, and FIG. 8E is a cross-sectional view illustrating a step of curing a preliminary functional layer.

In an embodiment and referring to FIG. 8D, the inverting of the display panel DP may be performed such that the preliminary functional layer PFL is positioned below the display panel DP. Specifically, the inverting of the display panel DP may be performed such that the preliminary functional layer PFL is positioned in a fourth direction DR4 opposite to the third direction DR3 with respect to the display panel DP. Since the preliminary functional layer PFL is positioned below the display panel DP, the resin may be discharged from the preliminary functional layer PFL through the plurality of holes Hs due to gravity. Specifically, the preliminary functional layer PFL receives a first pressure P1 in the fourth direction DR4 by the weight of the display panel DP, and the resin may be discharged through the plurality of holes Hs formed in the mask MSK by the first pressure P1. The discharged resin may be defined as a filtration resin LS. The filtration resin LS is an uncured resin, and may be removed by being discharged to the outside of the mask MSK through the plurality of holes Hs. The filtration resin LS may be removed by being discharged to the outside of the mask MSK by the first pressure P1 of the display panel DP and due to gravity of the filtration resin LS itself. The filtration resin LS may have the same configuration as the base portion BPb (see FIG. 8B).

In an embodiment, since the preliminary functional layer PFL has fluidity, the metal particles MP included in the preliminary functional layer PFL may move to a lower portion of the preliminary functional layer PFL due to gravity. Specifically, the metal particles MP may be concentrated in the lower portion of the preliminary functional layer PFL.

In an embodiment and referring to FIG. 8E, after the inverting of the display panel DP, curing the preliminary functional layer PFL may be further performed. A process of curing the preliminary functional layer PFL may include a process of curing the preliminary functional layer PFL through either thermal-curing or UV-curing the preliminary functional layer PFL inside a sealed chamber. According to an embodiment, the curing process may be the process of thermal-curing the preliminary functional layer PFL.

According to an embodiment, after the inverting of the display panel DP, pressurizing the preliminary functional layer PFL may be further performed. The pressurizing of the preliminary functional layer PFL may be performed through a separate pressure member in addition to pressurization by the weight of the display panel DP. The display panel DP receives a second pressure P2 in the fourth direction DR4 by the separate pressure member, and the preliminary functional layer PFL also receives the same second pressure P2 due to the second pressure P2 received by the display panel DP, so that the resin may be discharged through the plurality of holes Hs formed in the mask MSK. The pressurizing of the preliminary functional layer PFL may be performed before the curing of the preliminary functional layer PFL. However, the embodiment of the inventive concept is not limited thereto, and the pressurizing of the preliminary functional layer PFL and the curing of the preliminary functional layer PFL may be simultaneously performed. Since the pressurizing of the preliminary functional layer PFL and the curing of the preliminary functional layer PFL may be simultaneously performed, the curing of the preliminary functional layer PFL may be efficiently performed. The preliminary functional layer PFL may have adhesive force due to the curing.

FIG. 8F is a cross-sectional view illustrating removing the mask MSK disposed on the preliminary functional layer PFL (see FIG. 8E), in an embodiment.

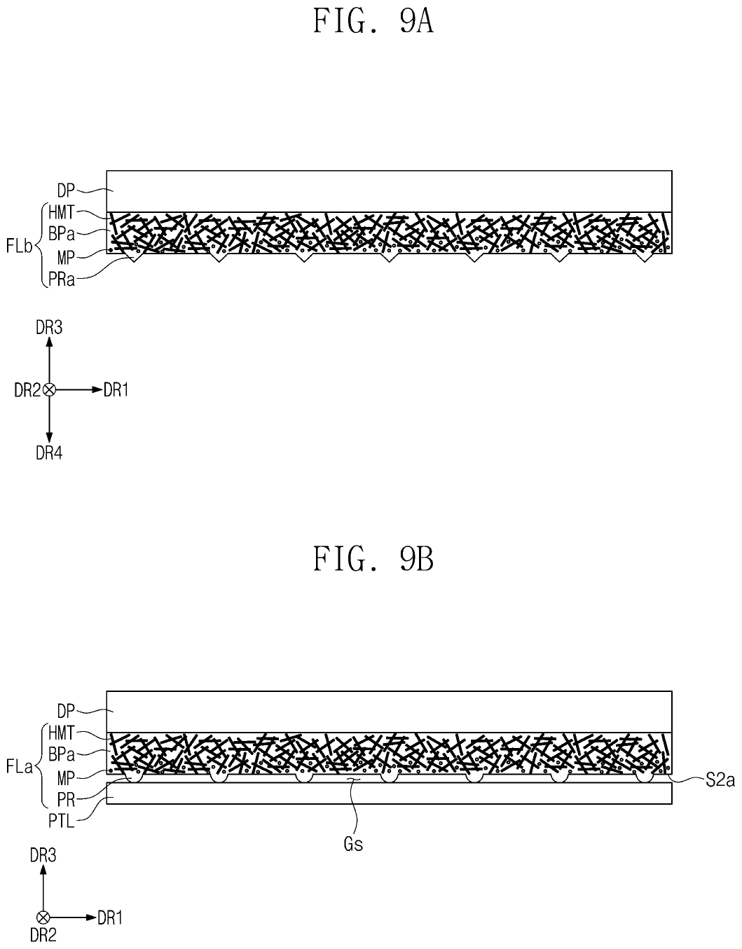

In an embodiment and referring to FIG. 8F, after the curing of the preliminary functional layer PFL, the mask MSK may be removed to form a functional layer FL. Specifically, after the curing of the preliminary functional layer PFL, the removing of the mask MSK and the filtration resin LS in contact with the mask MSK may be performed. In the process of removing the mask MSK, a fine protruded portion may be formed on the functional layer FL. Details thereof will be described with reference to FIG. 9A and FIG. 9B.

Referring to FIG. 8A to FIG. 8F, a method for forming the functional layer FL according to an embodiment may include inverting the preliminary functional layer PFL and then pressurizing and curing the same, so that the filtration resin LS is efficiently discharged from the preliminary functional layer PFL, and the thickness of the functional layer FL may be reduced due to the first pressure P1 of the display panel DP. In addition, the heat dissipation materials HMT included in the functional layer FL may be uniformly distributed at high density inside the base portion BP. Since the functional layer FL is thin, and the heat dissipation materials HMT are uniformly distributed at high density inside the base portion BP, the functional layer FL according to an embodiment of the inventive concept may have a high thermal diffusion coefficient. Since the functional layer FL has a high thermal diffusion coefficient, the heat HT generated from the electronic components may be efficiently dissipated so as not to be transmitted to the display panel DP. As a result, the reliable electronic apparatus ED (see FIG. 1) may be provided.

In addition, in an embodiment, since the preliminary functional layer PFL is inverted and then cured, the preliminary functional layer PFL has fluidity, so that the metal particles MP may be disposed in the lower portion of the functional layer FL due to gravity. Since the metal particles MP are disposed adjacent to a lower surface of the functional layer FL, the lower surface of the functional layer FL has conductivity, so that electromagnetic waves generated from electronic components such as the electronic module EM (see FIG. 2), the power source module PSM (see FIG. 2), and/or the electronic optical module EOM (see FIG. 2) disposed below the lower surface of the functional layer FL may be blocked. The functional layer FL may prevent electromagnetic waves generated from electronic components disposed below the display panel DP from being transmitted to the display panel DP as noise. In addition, even without a separate electromagnetic wave blocking layer disposed on the rear surface DP-B of the display panel DP, the functional layer FL has the effect of blocking electromagnetic waves, and thus may protect the display panel DP, and the electronic apparatus ED may have a simplified stacking structure.

FIG. 9A and FIG. 9B are cross-sectional views of some steps of a method for manufacturing an electronic apparatus according and an embodiment.

In an embodiment and referring to FIG. 9A, a functional layer FLb may include a plurality of protruded portions PRa respectively corresponding to the plurality of holes Hs (see FIG. 8C) of the mask MSK (see FIG. 8C). The plurality of protruded portions PRa may be portions formed by the filtration resin LS (see FIG. 8D) which have remained in the plurality of holes Hs as the mask MSK disposed on the functional layer FLb is removed. According to what is illustrated, the plurality of protruded portions PRa each have a pointed drill shape in the fourth direction DR4, but the shape thereof is not limited thereto. The plurality of protruded portions PRa may be arranged at a predetermined interval along the first direction DR1.

In an embodiment and referring to FIG. 9B, a protective layer PTL may be disposed below the functional layer FLa. The protective layer PTL disposed in a lower portion of the functional layer FLa may be in direct contact with the plurality of protruded portions PR. Since the plurality of protruded portions PR are in contact with the protective layer PTL, a gap Gs may be formed between the second surface S2a and the protective layer PTL.

In an embodiment, the plurality of protruded portions PR may be in direct contact with the protective layer PTL, and thus may have a hemispherical shape towards the protective layer PTL due to pressure. Since the functional layer FLa includes the plurality of protruded portions PR, and the gap Gs is formed between the second surface S2a and the protective layer PTL, an impact applied to the display panel DP (see FIG. 2) disposed on the functional layer FLa and/or to electronic components which may be disposed in a lower portion of the protective layer PTL may be absorbed.

An electronic apparatus according to an embodiment may have metal particles included in a functional layer and the metal particles may be disposed in a lower portion of the functional layer. Accordingly, the functional layer may have the effect of blocking electromagnetic waves, and may protect a display panel from the electromagnetic waves.

In a method for manufacturing the electronic apparatus according to an embodiment, the method may include inverting a preliminary functional layer and then pressurizing and curing the same, so that the thickness of a functional layer may be reduced, and heat dissipation materials included in the functional layer may be uniformly distributed at high density inside the functional layer. As a result, the functional layer may have a high thermal diffusion coefficient, and may efficiently dissipate heat generated from electronic components, thereby preventing the heat from being transmitted to a display panel.

Although the invention has been described with reference to embodiments, it will be understood by those skilled in the art that various modifications and changes in form and details may be made therein without departing from the spirit and scope of the present invention as set forth in the following claims.

Accordingly, the technical scope of the invention is not intended to be limited to the contents set forth in the detailed description of the specification, but is intended to be defined by the appended claims. The invention should not be construed as being limited to the embodiments set forth herein. Rather, these embodiments are provided so that this disclosure will be thorough and complete and will fully convey the concept of the invention to those skilled in the art. Moreover, the embodiments or parts of the embodiments may be combined in whole or in part without departing from the scope of the invention.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. An electronic apparatus comprising:
a display panel configured to display an image; and
a functional layer disposed on a rear surface of the display panel, wherein the functional layer includes:
a base portion including a first surface facing the rear surface and a second surface opposite to the first surface; and
heat dissipation materials and metal particles dispersed inside the base portion, wherein:
the metal particles are distributed more densely in a region closer to the second surface than in a region closer to the first surface.

2. The electronic apparatus of claim 1, wherein the functional layer is a single layer.

3. The electronic apparatus of claim 1, wherein the first surface is in contact with the rear surface of the display panel.

4. The electronic apparatus of claim 3, wherein the display panel comprises a base substrate defining the rear surface of the display panel and light emitting elements disposed on the base substrate,
wherein the first surface is in contact with the base substrate.

5. The electronic apparatus of claim 1, wherein the base portion comprises styrene-butadiene rubber.

6. The electronic apparatus of claim 1, wherein the heat dissipation materials comprise a carbon-based heat dissipation material.

7. The electronic apparatus of claim 1, wherein the functional layer further comprises a plurality of protruded portions protruding from the second surface.

8. The electronic apparatus of claim 7, further comprising a protective layer disposed in a lower portion of the functional layer,
wherein a gap is formed between the second surface and the protective layer by the protruded portions.

9. The electronic apparatus of claim 1, wherein a thermal diffusion coefficient of the functional layer is about 43 mm²/s.

10. The electronic apparatus of claim 1, wherein a thickness of the functional layer is about 100 μm to about 350 μm.

11. A method for manufacturing an electronic apparatus, the method comprising:
forming a preliminary functional layer by coating a resin, in which heat dissipation materials and metal particles are dispersed, on a rear surface of a display panel;
disposing a mask on the preliminary functional layer;
inverting the display panel such that the preliminary functional layer is positioned below the display panel; and
forming a functional layer by curing the preliminary functional layer.

12. The method of claim 11, further comprising, after the inverting of the display panel:
discharging the resin through a plurality of holes formed in the mask by a pressure caused by a weight of the display panel; and
removing the discharged resin.

13. The method of claim 12, wherein the forming the functional layer further comprises removing the mask.

14. The method of claim 13, wherein the functional layer comprises a plurality of protruded portions respectively corresponding to the plurality of holes formed in the mask.

15. The method of claim 14, further comprising, after the forming of the functional layer, disposing a protective layer below the plurality of protruded portions.

16. The method of claim 11, further comprising, after the inverting of the display panel, pressurizing the preliminary functional layer.

17. The method of claim 16, wherein the pressurizing of the preliminary functional layer and the curing of the preliminary functional layer are simultaneously performed.

18. The method of claim 11, wherein the forming the functional layer further comprises the curing of the preliminary functional layer by thermal curing.

19. The method of claim 11, further comprising, before the inverting of the display panel, pre-curing the preliminary functional layer.

20. The method of claim 19, wherein the pre-curing of the preliminary functional layer is performed by thermal curing.
